(19) United States
(12) Patent Application Publication
(10) Pub. No.: US 2026/0038562 A1
(43) Pub. Date: Feb. 5, 2026

(54) APPARATUSES SYSTEMS AND METHODS FOR LINKED BANK REFRESH

(71) Applicant: Micron Technology, Inc., Boise, ID (US)

(72) Inventors: Yang Lu, Boise, ID (US); Donald M. Morgan, Meridian, ID (US); Kang-Yong Kim, Boise, ID (US); Gary Howe, Allen, TX (US); Sujeet Ayyapureddi, Boise, ID (US)

(73) Assignee: Micron Technology, Inc., Boise, ID (US)

(21) Appl. No.: 18/790,036

(22) Filed: Jul. 31, 2024

(51) Int. Cl. G11C 11/406; G11C 11/408

(52) U.S. Cl. CPC G11C 11/40618; G11C 11/40615; G11C 11/4087

(57) ABSTRACT

A memory device includes a plurality of memory banks. The memory device receives a linked activation command along with a bank address which specifies a first one of the memory banks. While an access operation is performed on the first memory bank responsive to the linked activation command, a refresh operation is performed on a second memory bank responsive to the linked activation. The first and the second memory banks are part of a bank link group. A second linked activation command may be received a time after first linked activation command which is less than a refresh delay tRFCL as long as the second linked activation command is to a different bank link group.

### BACKGROUND

This disclosure relates generally to semiconductor devices, and more specifically to semiconductor memory devices. In particular, the disclosure relates to volatile memory, such as dynamic random access memory (DRAM). Information is stored in the memory on memory cells as a physical signal such as a charge on a capacitive element. During an access operation, an access command may be received on a command and address bus along with address information which specifies which memory cells should be accessed.

Information may decay over time in the memory cells. For example, the memory cells may discharge over time. In order to preserve the integrity of the stored information, the memory cells may be refreshed, for example to restore an initial charge level associated with the stored information. The memory receives a refresh command on said command and address bus which instructs it to perform one or more refresh operations. However, the refresh command occupies the command and address bus which may be unavailable to accept access commands due to bandwidth limits. It may be desirable to find ways to reduce the amount of time the command and address bus is unavailable for access operations while still making sure that refresh operations are occurring.

### BRIEF DESCRIPTION OF THE DRAWINGS

FIG. 1 is a block diagram of a semiconductor device according to some embodiments of the disclosure.

FIG. 2 is a block diagram of bank logic circuits according to some embodiments of the present disclosure.

FIGS. 3A-3C are block diagrams of example bank link groups according to some embodiments of the present disclosure.

FIG. 4 is a table of a command address packet according to some embodiments of the present disclosure.

FIG. 5 is a timing diagram of linked refresh operations according to some embodiments of the present disclosure.

FIG. 6 shows timing charts of example operations performed on a memory device according to some embodiments of the present disclosure.

FIG. 7 is a timing diagram of linked refresh operations in two bank link groups according to some embodiments of the present disclosure.

FIG. 8 is flow chart of a method of performing linked activation commands according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells. The memory cells are at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

During an access operation such as a read or write operation, the memory receives access commands and a bank, row, and column address on a command and address bus. The memory receives a row activation command and activates the word line specified by the row address in the bank specified by the bank address. While active, data may be read or written along the bit lines specified by the column address responsive to column commands such as read or write commands. The bit lines are coupled to sense amplifiers. The sense amplifiers sense a voltage on the bit line from the memory cells along the active word line and amplify it into a signal in a read operation or drive a voltage to the memory cell along the active word line in a write operation.

During a refresh operation, the memory receives a refresh command on the command and address bus that specifies one or more banks, such as a per-bank refresh command, same bank refresh command or all bank refresh command. Responsive to the command, the specified bank(s) performs one or more refresh operations on a row-by-row basis. However, while-receiving refresh operation commands, the memory device may be unable to receive access operation commands due to a finite bandwidth of the command and address bus. Per-bank refresh commands may be especially costly to bandwidth, as more refresh commands are required because refresh operations are only performed on a single bank for each per-bank refresh command. It may be useful to combine operations so that banks can be refreshed without necessarily requiring an explicit refresh command.

The present disclosure is drawn to apparatuses, systems, and methods for linked bank refresh operations. A memory device of the present disclosure can receive a normal access command or a linked bank access command. For example, the row activation command may specify whether it is a normal command ACTN or a linked command ACTL. The linked bank access command specifies a bank to be accessed as well as one or more banks which are linked to the accessed bank. While the access operation is being performed on the specified bank, one or more refresh operations may be performed in the specified one(s) of the linked banks. Since activation commands are relatively common, the use of linked bank activation commands may allow for refresh operations to occur relatively frequently. In addition, the use of linked access commands may improve the bandwidth of the memory by allowing more flexibility in access commands. For example, access to the linked banks may be restricted until a time tRFCL has elapsed. However, certain commands may still be issued to the bank specified by the bank address for the access operation, and commands may be provided to other banks which are not part of the linked banks.

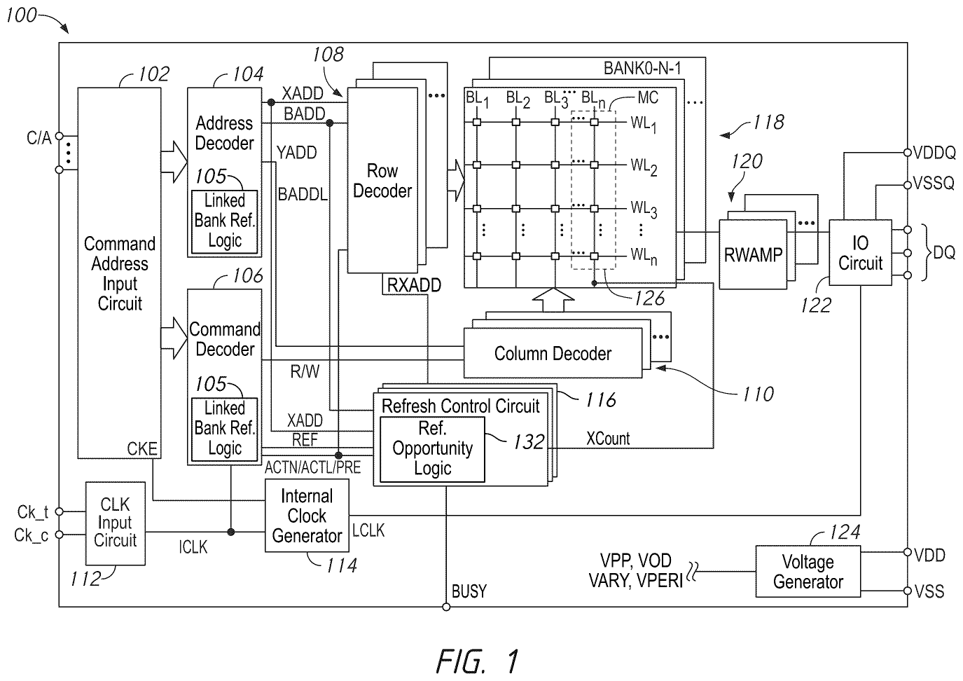

FIG. 1 is a block diagram of a semiconductor device according to some embodiments of the disclosure. The semiconductor device 100 may be a semiconductor memory device, such as a DRAM device integrated on a single semiconductor chip. In some embodiments, the semiconductor device 100 may represent one of a number of memory devices packaged together, such as on a module. In some embodiments, the semiconductor device 100 may represent a stand-alone memory device.

The semiconductor device 100 includes a memory array 118. The memory array 118 is organized into a plurality of memory banks. In the embodiment of FIG. 1, the memory array 118 is shown as including N memory banks labeled BANK0 to BANKN−1. For example, a memory array 118 may include 4, 8, 16, 32 or any other number of memory banks. More or fewer banks may be included in the memory array 118 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP, and transferred to read/write amplifier (RWAMP) circuit 120 over local data lines (LIO), transfer gate (TG), and global data lines (GIO). Conversely, write data outputted from the RWAMP circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A or CA) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ. The external terminals may also generally be referred to as ‘pins’ such as C/A pins. In some embodiments, the external terminals may couple directly to a host or controller of the memory device 100. In some embodiments, the external terminals may couple to various buses/connectors of a module or other package. In some embodiments, each terminal may generally receive a first voltage which represents a logical high or a second voltage which represents a logical low. Other schemes, such as multi-level signaling (e.g., PAM4) may be used in other example embodiments.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command and address input circuit 102, to an address decoder 104. The address decoder 104 decodes the address into a bank address, row address, and column address. The bank address BADD selects the row decoder 108 and column decoder 110 and thus selects the bank. The address decoder 104 supplies a decoded row address XADD to the row decoder 108 selected by BADD and supplies a decoded column address YADD to the column decoder 110 selected by BADD. The decoded row address XADD may be used to determine which row is opened or activated, coupling the memory cells along the activated word line to the intersecting bit lines. The column decoder 110 provides a column select signal CS based on the column address YADD. The CS signal selects which bit lines are coupled to local input/output lines, allowing those bit lines to be accessed.

The C/A terminals may be supplied with commands. Examples of commands include timing commands for controlling the timing of various operations, access commands for accessing the memory, such as row activation commands, read commands for performing read operations, write commands for performing write operations, and pre-charge commands, refresh commands such as all-bank refresh, same bank refresh, and per-bank refresh, as well as other commands and operations. The access commands may be associated with one or more row address XADD, column address YADD, and bank address BADD to indicate the memory cell(s) to be accessed. In some embodiments, the command and address may be transmitted together as a command packet along the C/A terminals. The input circuit 102 separates the command portion of the packet from the address portion and provides the command portion to the command decoder 106 and the address portion to the address decoder 104. An example access command includes an activation command packet ACT, which includes the activation command, row address, and bank address.

The memory device 100 may receive a normal access command or a linked access command. The present disclosure is generally described with respect to a normal row activation command ACTN or a linked row activation command ACTL. However, other commands, such as the pre-charge command, may be used in other example embodiments. The normal row activation command ACTN causes the memory to perform an access operation on a bank specified by a bank address BADD. The linked row activation command ACTL causes the memory to perform an access operation on a bank specified by the bank address BADD and gives memory the opportunity to perform a linked refresh operation in one or more banks linked to the bank specified by BADD. In some embodiments, which bank is given the linked refresh opportunity may be inherent to the structure of the memory. In some embodiments, the memory device 100 may receive a linked bank address BADDL which indicates which bank in the linked group of banks is being given the linked refresh opportunity. In some embodiments, the memory device 100 may receive a linked bank address BADDL which additionally indicates which of the banks are linked with the bank specified by BADD.

The commands may be provided as internal command signals to a command decoder 106 via the command and address input circuit 102. The command decoder 106 includes circuits to decode the internal command signals to generate various internal signals and commands for performing operations. For example, the command decoder 106 may provide signals to indicate if data is to be read, written, etc. Responsive to an activation command received at the C/A terminals, as part of an access operation the command decoder 106 provides an internal row activation command or internal row activation signal ACTN or ACTL. Responsive to a pre-charge command the command decoder 106 provides an internal pre-charge command or internal pre-charge signal Pre. The row decoder 108 activates a word line responsive to the internal activation signal ACT and deactivates (or pre-charges) the word line responsive to the internal pre-charge signal Pre.

The address decoder 104 includes linked bank refresh logic circuits 105 and the command decoder 106 includes linked bank refresh logic circuits 107. The linked bank refresh logic circuits 105 and 107 receive respective command and address portions of a command address packet received by the command address input circuit 102. The linked bank refresh logic circuit 107 receives the command bits and determines if the command is a normal or linked activation command, and provides internal signals such as a normal activation signal ACTN, linked activation signal ACTL, and refresh signal REF. The linked bank refresh logic 105 receives the address portion of the packet and provides a bank address BADD which specifies the accessed bank and if applicable a linked bank address BADDL which specifies where the linked refresh opportunity is. As described in more detail herein, each bank has an associated refresh control circuit 116, and refresh opportunity logic circuits 132 of the refresh control circuit 116 associated with the linked bank will determine whether or not to perform a refresh operation.

In an example write operation, the device 100 writes data received at the DQ terminals to the memory cells specified by a received bank, row and column address. As part of the write operation, the command decoder 106 receives an activation command ACTN or ACTL and a write command and provides internal signals such as W and ACTN/ACTL/Pre. The write data is received by the IO circuit 122 and provided to the RWAMP circuit 120. The row decoder 108 selected by BADD activates the row selected by XADD responsive to the internal activation signal ACTN or ACTL. The column decoder 110 selected by BADD couples the bit lines selected by YADD to the LIO and GIO lines to the RWAMP circuit 120. The sense amplifiers drive the voltages on the coupled bit lines to write the write data to the memory cells at the intersection with the active word line. If the command was a linked activation command and ACTL is provided, then the refresh control circuit 116 of a linked bank, for example as specified by BADDL, may perform one or more refresh operations.

In an example read operation, the device 100 reads data from the memory cells specified by a received bank, row, and column address and provides that read data to the DQ terminals. As part of the read operation, the command decoder 106 receives an activation command ACTN or ACTL and a read command and provides internal signals such as a read signal R, and ACTN/ACTL/Pre. The row decoder 108 selected by BADD activates the row selected by XADD responsive to the internal row activation signal ACT. The column decoder 110 selected by BADD couples the bit lines selected by YADD to the LIO and GIO lines to the RWAMP circuit 120. The RWAMP circuit 120 provides the read data to the IO circuit 122 and the IO circuit 122 provides the read data to the DQ terminals. If the command was a linked activation command and ACTL is provided, then the refresh control circuit 116 of a linked bank, for example as specified by BADDL, may perform one or more refresh operations.

The device 100 includes refresh control circuits 116 each associated with a bank of the memory array 118. Each refresh control circuit 116 may determine when to perform a refresh operation on the associated bank. The refresh control circuits 116 receive a command, address, or combinations thereof as part of an access operation that indicate a refresh opportunity, as described in more detail herein. For example, the command decoder 106 may receive a linked activation command ACTL. Responsive to ACTL, the refresh control circuit 116 may determine that there is a linked refresh opportunity and determine whether to use that opportunity to perform a linked refresh operation. A linked refresh operation is performed on a bank while an access is being performed on another bank.

As well as linked refresh commands, the memory device 100 may also receive explicit refresh commands, such as all-bank refresh commands, per-bank refresh commands, or same-bank refresh commands. Responsive to an explicit refresh command, the refresh control circuit 116 may also determine that there is a refresh opportunity and determine whether or not to perform a refresh operation. In contrast to a linked refresh operation, explicit refresh commands happen on their own and are not associated with other operations such as access operations. All-bank refresh commands involve the entire memory which may generally prevent other operations from occurring concurrently for a specified length of time tRFC. Per-bank refresh commands and same-bank refresh commands refresh a subset of the banks of memory device 100, and may allow other banks which are not being refreshed to be available for commands such as activate commands, write commands, and read commands if command and address bus bandwidth is available.

When the refresh control circuit 116 determines that there is a refresh opportunity for that bank, either explicit or linked, the refresh control circuit 116 determines whether or not to perform a refresh operation. For example, the refresh control circuit 116 may determine whether or not to perform a refresh operation based at least in part on if a refresh operation is called for, and if a refresh operation is possible. The refresh control circuit 116 may include refresh opportunity logic circuits 132 which determine whether or not to perform a refresh operation. If the refresh control circuit determines to perform a refresh operation, the refresh control circuit 116 performs a refresh operation by generating a refresh address RXADD. The row decoder 108 refreshes one or more word lines associated with RXADD. If the refresh is a linked refresh operation, the refresh address RXADD is provided to a row decoder 108 associated with the linked bank (e.g., BADDL) and the refresh is performed while the word line associated with XADD is being accessed in the bank specified by BADD as part of the access operation.

Refresh operations may include one or more normal refresh operations, one or more targeted refresh operations, or combinations thereof. In a normal refresh operation, the refresh address is generated based on sequence logic. For example a refresh address counter may increment to generate a new refresh address, such as RXADD (i)=RXADD (i−1)+1. In a targeted refresh operation, an identified aggressor address is used to generate refresh addresses. The refresh addresses may be adjacent to the aggressor, for example RXADD=Aggressor+/−1.

The refresh control circuit 116 also tracks accesses to word lines of the respective banks to determine if a targeted refresh operation should be performed. Memory cells along each word line are set aside as counter memory cells 126. The counter memory cells store a per-row access count (PRAC) value associated with a number of times that the respective word line has been accessed. When a word line is accessed or refreshed, its PRAC value is read out to the refresh control circuit 116 which updates (e.g., increments) the count value and determines if the count has crossed a threshold as part of an access count update (ACU) operation. If the PRAC value has crossed a mitigation threshold, then the address is added to an aggressor queue for a later targeted refresh operation. When a targeted refresh operation is performed, one or more victim word lines of the aggressor word line are refreshed.

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

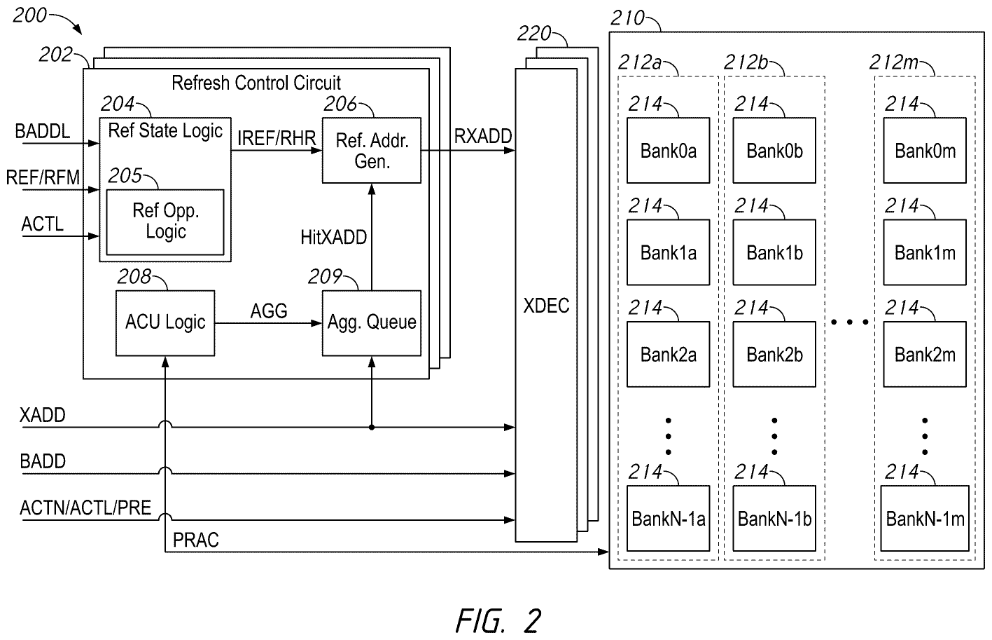

FIG. 2 is a block diagram of bank logic circuits according to some embodiments of the present disclosure. The bank logic circuits 200 may, in some embodiments, represent a portion of the memory device 100 of FIG. 1. The bank logic circuits 200 show refresh logic circuits 202 (e.g., 116 of FIG. 1), row decoders 220 (e.g., 108 of FIG. 1) and memory array 210 (e.g., 118 of FIG. 1). The memory array 210 is divided into a number of banks 214. There is a refresh control circuit 202 and row decoder 220 associated with each bank. Since the refresh control circuits 202 and row decoders 220 may be generally similar to each other, only one will be described in detail as an example.

The memory array 210 is divided into a number of memory banks 214. Some of the banks are linked together in link groups 212. In the embodiment of FIG. 2, there are M link groups 212, each with N banks 214 for a total of N×M banks 214. Each bank contains its own respective set of bit lines, word lines, and memory cells. For the sake of understanding, in FIG. 2 the banks are indexed as Bankij, where i is the relative position f that bank in the link group, and j is an index of the link group. So for example Bank0a to BankN−1a are all in link group a 212a, while Bank0a and Bank0b are in different link groups 212a and 212b respectively. This convention is for ease of understanding only. In a memory device each bank may have a numerical designation, and for example Bank0 and Bank1 may be in a first link group, Bank2 and Bank3 may be in a second link group, and so forth.

When a bank is accessed, one or more of the other banks in the same link group 212 as the accessed bank is given a link refresh opportunity. For example, if Bank0a is specified by bank address BADD for an access operation, then one or more of the other banks in link group A 212a will be given a link refresh opportunity. In some embodiments, the link groups 212 may be pre-defined. For example banks Bank0a to BankN−1a may be in a set group. In some embodiments, which banks are in which link groups 212 may be a setting of the memory, such as a setting of a mode register. In some embodiments, which banks are in which link groups 212 may be determined by the linked access command received by the memory. For example, the linked access command may specify which banks are linked together.

In some embodiments, which of the other banks in the link group receives a linked refresh opportunity may be determined by the memory device. For example, if there are only two banks in each link group, then it is not necessary to specify which other bank receives the linked refresh opportunity. In some embodiments, if there are multiple banks in each link group, the memory may use internal logic to determine which other bank(s) get the linked refresh opportunity. In some embodiments, the linked access command may include a linked bank address BADDL, which specifies which of the other banks in the link group receives the linked refresh opportunity. For example, if the bank address BADD specifies bank Bank0a in link group 212a, then the linked bank address BADDL specifies which of banks Bank1a to BankN−1a receives a linked bank refresh opportunity.

The refresh control circuit 202 includes a refresh state logic circuit 204, a refresh address generator circuit 206, an ACU logic circuit 208, and an aggressor queue 209. The refresh state logic circuit 204 determines if one or more refresh operations should be performed, what type(s) should be performed, and how many operations should be performed. The refresh address generator 206 generates a refresh address RXADD for each refresh operation. The ACU logic 208 manages ACU operations to determine which addresses are aggressor addresses to be stored in the aggressor queue 209.

During an access operation, the bank logic 200 receives a bank address BADD and row address XADD. Responsive to an activation signal ACTN or ACTL, the row decoder 220 specified by the bank address BADD accesses the specified bank 214 and activates the word line specified by XADD. Responsive to the signal Pre, the specified row decoder 220 pre-charges the word line. While the word line is active, its PRAC value is read out to the ACU logic circuit 208, which updates the PRAC value and writes it back. For example, the ACU logic circuit 208 may perform a read/modify/write cycle on the counter memory cells (e.g., 126 of FIG. 1).

The ACU logic circuit 208 compares the updated PRAC value to a mitigation threshold. For example, the ACU logic circuit 208 may increment the PRAC value and determine if it is equal to or greater than the mitigation threshold. If the PRAC value has crossed the mitigation threshold, then the ACU logic circuit 208 provides an aggressor signal AGG. Responsive to the aggressor signal AGG, the aggressor queue 209 stores the current address XADD as an aggressor address.

The refresh control circuit 202 receives signals such as a refresh signal REF, refresh management signal RFM, and linked access signal such as ACTL which indicate that a refresh should be performed or that there is an opportunity for a refresh operation. For example, in some embodiments, the refresh signals REF and RFM are provided responsive to explicit refresh commands, and the refresh control circuit will perform refreshes responsive to those signals, while the signal ACTL may represent a refresh opportunity. In other embodiments, REF and RFM may also represent opportunities for refresh operations. Different mixes of which signals are used to command refresh operations and which are refresh opportunities may be performed in other embodiments.

The refresh state logic circuit 204 includes one or more refresh opportunity logic circuits 205 which determine whether or not to perform refresh operations when a refresh opportunity is provided. In some embodiments, the refresh opportunity logic 205 may compare the number of refreshes which have been performed in the associated bank to an expected number of refresh operations to have been performed on that bank. For example, the refresh opportunity logic may compare a refresh address counter to a counter of the number of refresh intervals tREFI which have elapsed in a current refresh period to determine if a refresh operation should be performed. Instead, or in addition, the refresh opportunity logic 205 may check a status of the aggressor queue 209. If there are no stored aggressor addresses, then the refresh opportunity logic 205 may skip performing refresh operations when there is an opportunity.

The refresh state logic circuit 204 performs refresh operations by providing internal refresh signals IREF and RHR. The internal refresh signal IREF indicates a normal refresh operation, while the targeted refresh signal RHR indicates a targeted refresh operation. The refresh state logic circuit 204 may issue multiple activations of one or both of IREF and RHR when given the opportunity to perform refresh operations. For example, responsive to REF or to a linked refresh signal ACTL, the refresh state logic 204 may provide a mix of IREF and RHR to perform a mix of normal and targeted refresh operations. Responsive to RFM, only targeted refresh operations may be performed.

The refresh address generator circuit 206 provides a refresh address RXADD responsive to IREF or RHR. Responsive to IREF, the refresh address generator circuit 206 generates the refresh address based on sequence logic. For example, a refresh address counter may be incremented and used to generate the refresh address. Responsive to RHR, the refresh address generator circuit 206 uses an aggressor address HitXADD provided by the aggressor queue 209 to generate the refresh address RXADD. For example, the refresh address generator circuit 206 may refresh the word lines on either side of the aggressor, and then reset the PRAC value along the aggressor.

In an example operation, the memory receives a row address XADD and linked activation command ACTL along with a bank address BADD and linked bank address BADDL. A first row decoder associated with BADD activates the word line specified by XADD in a first bank specified by BADD. The PRAC value associated with that active word line is read out to the respective refresh control circuit 202 and updated as part of an ACU operation. As part of the same operation, a second refresh control circuit associated with a second bank which is part of the same link bank group as the first bank receives a refresh opportunity. For example, the second refresh control circuit may be specified by BADDL. Responsive to BADDL and ACTL, the refresh opportunity logic 205 of the second refresh control circuit determines whether or not to perform a refresh operation. If the refresh opportunity logic 205 determines to perform a refresh operation, then the refresh state logic circuit 204 provides one or more activations of IREF, RHR, or combinations thereof, and performs one or more refresh operations. In this manner, responsive to a linked activation command ACTL, both an access operation on a first bank and a refresh operation on a second bank may be performed.

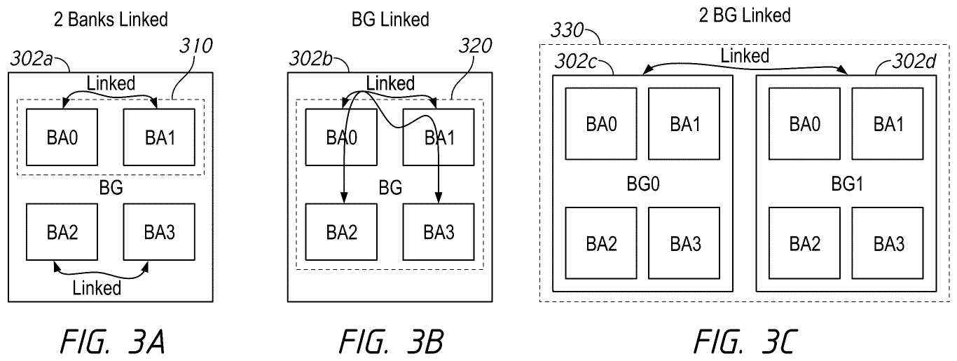

FIGS. 3A-3C are block diagrams of example bank link groups according to some embodiments of the present disclosure. FIG. 3 shows 3 example arrangements of how bank link groups (e.g., 212a-212m of FIG. 2) may be formed. FIGS. 3A-3C each show an example bank group or bank groups 302a-302d. Each bank group includes a respective four banks, BA0, BA1, BA2, and BA3. The banks shown in FIGS. 3A-3C may in some embodiments, represent banks in a memory array such as 118 of FIGS. 1 and/or 210 of FIG. 2. Each of the FIGS. 3A-3C shows different examples of ways that banks may be linked. The bank groups 302a-302d may represent examples of one (or two) of several bank groups in the array. An example memory array may include 32 memory banks, in 8 total bank groups in some embodiments.

FIG. 3A shows a bank group 302a where the bank link group 310 includes two banks. For example, banks BA0 and BA1 are in link group 310. Banks BA2 and BA3 would be in a different link group together. FIG. 3B shows a bank group 302b where the bank link group 320 includes all four banks in the bank group. For example, BA0, BA1, BA2, and BA3 are all in the link group 320. FIG. 3C shows two bank groups 302c and 302d which are linked together. In the embodiment of FIG. 3C, eight banks are linked together in the bank group 330.

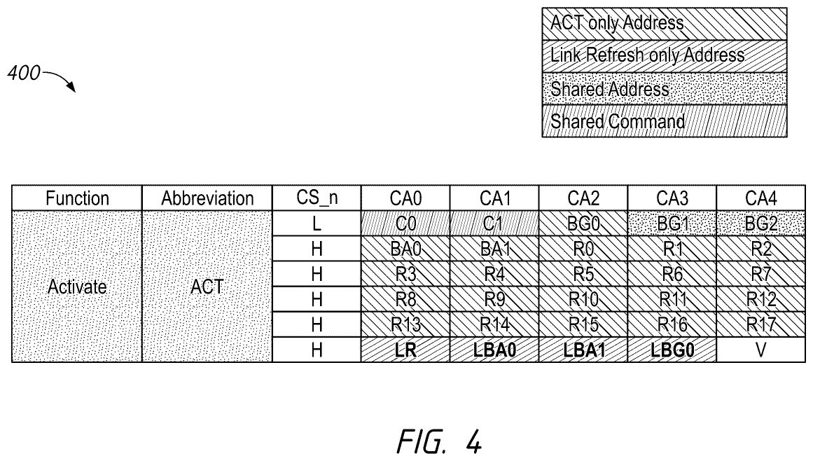

FIG. 4 is a table of a command address packet according to some embodiments of the present disclosure. FIG. 4 shows a table 400 which represents an example of how a linked activation command ACTL and linked bank address BADDL may be provided across the command and address bus according to some embodiments of the present disclosure. For example, the table 400 may represent signals which are received along the C/A terminals by the command address input circuit 102 of FIG. 1 in some embodiments.

The table 400 is organized showing signals along five CA terminals CA0 to CA4. Each of these terminals receives a burst of six bits in a sequential burst, for 30 total bits in the packet. Eighteen of those bits are used for the row address R0 to R17. The remaining bits are used to indicate an activation command, the bank address, as well as if the activation command is a linked activation command or not. Some of the bits may be shared between the accessed bank address BADD and the linked bank address BADDL. The number of bits which are shared may be based in part, on the implementation of how many banks are grouped together. For example, the table 400 may represent an embodiment where two bank groups are linked together, similar the embodiment of FIG. 3C.

The table 400 shows bits CO and Cl to select an activation command and a bit LR which is at an active level if the command is a linked activation command ACTL, and inactive if the command is a normal activation command ACTN. Also shown are bank address bits BG0, BG1, BG2, BA0, and BA1. The bits BG0-BG2 specify one of eight bank groups, and the bits BA0 and BA1 specify one of the four banks within that bank group. Together these bits make up BADD. Also shown linked bank address bits LBA0, LBA1, and LBG0. These bits, together with BG1 and BG2 make up the linked bank address BADDL. In this way, the bits BG1 and BG2 are shared between the two bank addresses BADD and BADDL. The shared portion BG1 and BG2 specify one of four pairs of bank groups. The bit LBG0 specifies which bank group in the pair is receiving a linked refresh opportunity, and the bits LBA0 and LBA1 specify which bank within the one of the pair of groups specified by LBG0 is receiving a linked refresh opportunity.

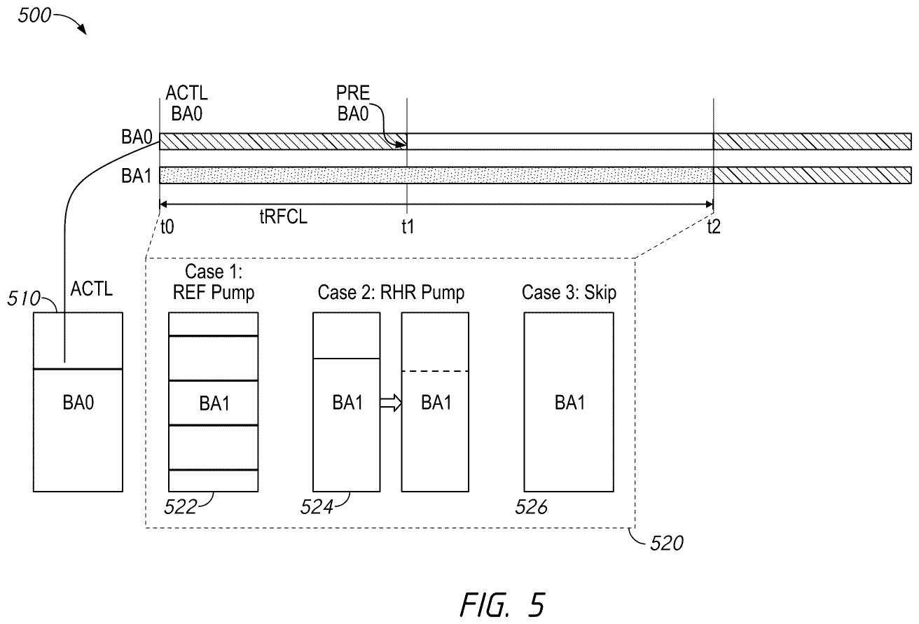

FIG. 5 is a timing diagram of linked refresh operations according to some embodiments of the present disclosure. The timing diagram 500 may, in some embodiments, represent operations of a memory device such as 100 of FIG. 1, or bank logic such as 200 of FIG. 2. The timing diagram 500 represents an access operation to a first bank and a linked refresh operation in a second bank which is part of the same bank link group as the first bank.

The timing diagram 500 represents operations, with the upper line representing an access operation in a first bank BA0 and the lower line represents a linked refresh operation being performed in a second bank BA1. Insets 510 and 520 are representations of the operations being performed in BA0 and BA1 respectively.

At an initial time t0, a linked activation command ACTL along with the bank address for BA0. The bank BA1 is given a linked refresh opportunity, for example based on a linked bank address received with the linked activation command. As shown by the inset 510, a row in the bank BA0 is activated responsive to the activation command ACTL, represented by the horizontal line. At a time t1, a pre-charge command is received for bank BA0, and the word line is pre-charged.

Starting at the time to, one or more refresh operations may be performed on the bank BA1. Inset 520 shows three possible options 522-526 for the refresh operation which may be performed. In the embodiment of FIG. 5, one of the three options may be performed. The first option 522 shows a normal refresh operation, with four word line simultaneously refreshed. For example, the refresh address RXADD may mask two bits compared to a full row address, and so the refresh address may match to four addresses. The option 524 represents two targeted refresh operations on a first word line and a second word line. The second targeted refresh operation may be optional. For example, if there is only one address in the queue, and only targeted refresh remains to be performed based on that address, then the second targeted refresh will be skipped. The option 526 represents skipping performing a refresh operation entirely.

The refresh operations in bank BA1 may take up a linked refresh time tRFCL. The time tRFCL runs from t0 to a time t2. During the period of tRFCL, no access commands can be issued to the bank BA1 (since it is busy performing refresh operations). During the time between t0 and t1, no accesses can be issued for bank BA0, since it is busy with the access operation commanded by ACTL. After the time t1, when the pre-charge command is received, a linked activation command ACTL cannot be issued for bank BA0, however, the command ACTL may be issued to other banks. After the time t2, when tRFCL has elapsed, then there are no more restrictions on commands.

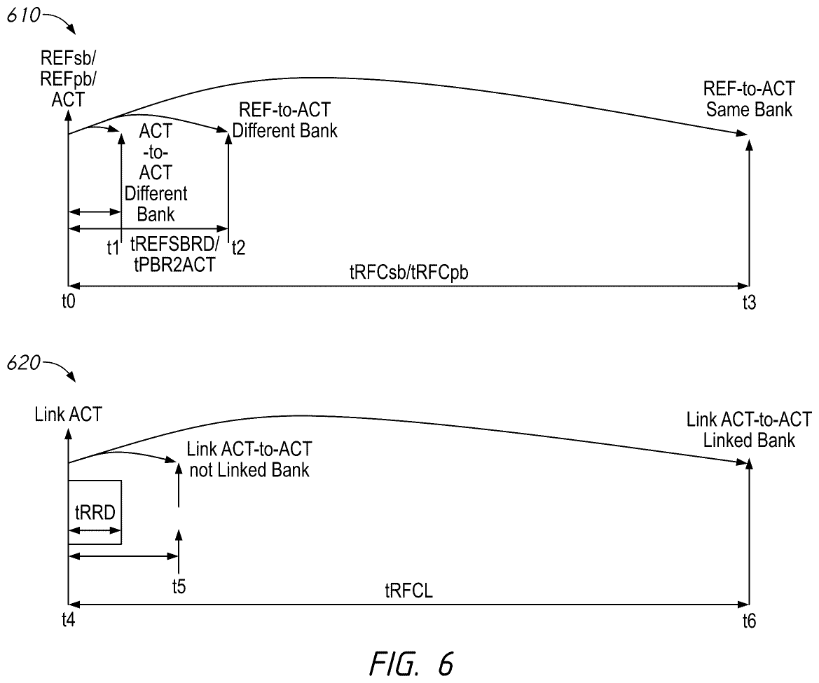

FIG. 6 shows timing charts of example operations performed on a memory device according to some embodiments of the present disclosure. The timing charts 610 and 620 represent commands issued to the device and show representations of the timing restrictions those different commands may have. The timing charts may represent the operations of a memory device such as 100 of FIG. 1. For example, the timing charts 610 and 620 may represent the operations of a bank logic circuit such as 200 of FIG. 2 responsive to different commands.

The timing chart 610 shows timing restrictions from a non-link activate ACT or an explicit refresh command such as REFsb or REFpb. At a time t0, the command is received. If the command was a non-link activate command, then an activation command may be received to a different bank at t1 which is a row to row delay specification time tRRD after t0. If a refresh operation is performed in response to a same-bank refresh command or a per-bank refresh command, there is a delay of tREFSBRD or tPBR2ACT before a next activation can be performed. At the time t2, after tREFSBRD or tPBR2ACT has elapsed, an activation may be performed on a different bank. However, if the activation is directed to the same bank as the one which received the explicit refresh command, a time rRFCsb or tRFCpb must be waited out, until a time t3, when a next ACT may be received on that bank.

The timing chart 620 shows a linked activation command, which is received at a time t4. After the time t4, a delay time must elapse which must not be less than tRRD. At a time t5, an activation command may be received for a different bank which is not part of the same linked bank group. The delay between t4 and t5 may be similar to the delay between t0 and t1, and shorter than the delay between t0 and t2. At a time t6, a next activation may be performed on one of the banks in the same link group. The delay between t4 and t6 is tRFCL.

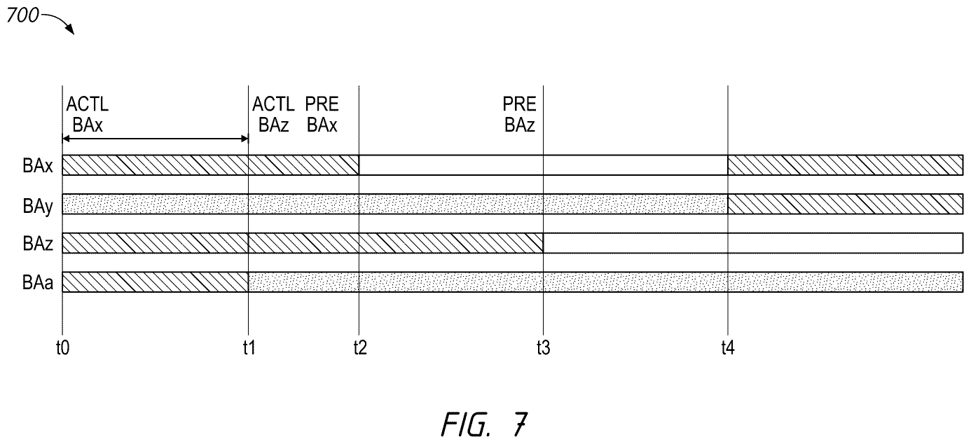

FIG. 7 is a timing diagram of linked refresh operations in two bank link groups according to some embodiments of the present disclosure. The timing diagram 700 may represent the operation of one or more of the apparatuses or systems described herein. For example, the timing diagram 700 may represent the operation of a memory device such as 100 of FIG. 1 and/or bank logic such as 200 of FIG. 2. The embodiment of FIG. 7 represents an alternate timing specification compared to the embodiment of FIG. 5. In the embodiment of FIG. 7, more overlap is allowed between linked activation commands to different bank groups. In other words, the delay between when a linked activation command is received by a first bank link group and a linked activation command may be received by a second bank link group may be shorter than the delay described with respect to FIG. 5.

The timing diagram 700 may be generally similar to the timing diagram 500 of FIG. 5, except the timing diagram 700 shows four banks in two different bank link groups. Banks BAx and BAy are in a first bank link group and banks BAz and BAa are in a second bank link group. For example, the banks BAx and BAy may represent banks BA0 and BA1 of FIG. 3A while the banks BAz and BAa may represent banks BA2 and BA3 of FIG. 3A.

At an initial time t0, the memory receives a linked activation command ACTL along with a bank address for bank BAx. In some embodiments, the linked activation command ACTL may be received along with a linked bank address which indicates bank BAy. In some embodiments, the linked activation command may not need to include a linked bank address, for example if bank BAy is the only other bank in the first bank link group. At the time t0, a row is activated in the first bank BAx by a row decoder (e.g., 108 of FIGS. 1 and/or 220 of FIG. 2) based on a row address (not shown) also received along with the linked activation command. At the time t0, a refresh control circuit (e.g., 116 of FIGS. 1 and/or 202 of FIG. 2) performs a refresh operation on the bank BAy. For example, the refresh control circuit may perform a normal refresh operation (e.g., 522 of FIG. 5), perform one or more targeted refresh operations (e.g., 524 of FIG. 5), or skip performing a refresh operation (e.g., 526 of FIG. 5).

The bank BAx is unavailable until a time t2 which is after a pre-charge command is received for the bank BAx. The time between t0 and t2 may be at least a row to row delay time tRRD. The bank BAy is unavailable from a time from t0 to a time t4. This time may represent a linked refresh delay time tRFCL.

At a time t1, which is before t2, a linked activation command ACTL is received for the bank BAz. Since the bank BAz is part of a different bank link group from the banks BAx and BAy, the bank BAz may receive a linked activation command. Similar to the banks BAx and BAy, at the time t1 a row decoder associated with the bank BAz activates a word line in the bank BAz, and a refresh control circuit associated with the bank BAa performs a refresh operation on the bank BAa. The refresh operation may be a normal refresh operation, one or more targeted refresh operations, or the refresh control circuit may skip performing the refresh operation. At a time t3, which is after t2, but before t4, a pre-charge command is received for the bank BAz.

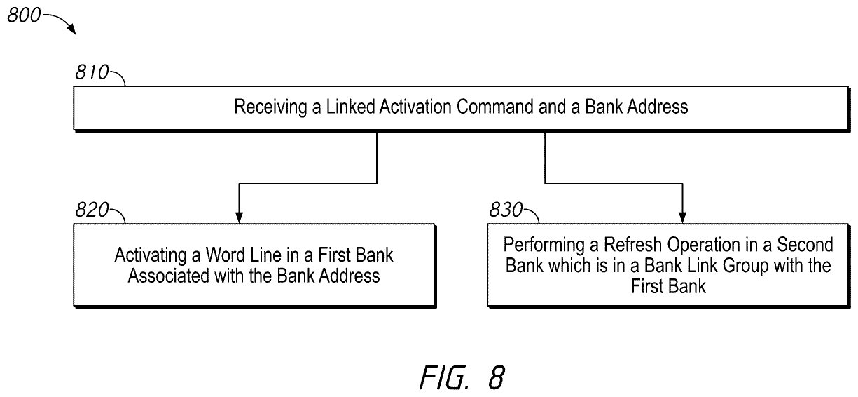

FIG. 8 is flow chart of a method of performing linked activation commands according to some embodiments of the present disclosure. The method 800 may, in some embodiments, be performed by one or more of the apparatuses or systems described herein. For example, the method 800 may be performed by a memory device such as 100 of FIG. 1 and/or bank logic such as 200 of FIG. 2.

The method 800 may generally begin with box 810, which describes receiving a linked activation command and a bank address. The linked activation command and bank address may be received as part of a command address packet (e.g., 400 of FIG. 4). The method 800 may include receiving the linked activation command and bank address with a command address input circuit (e.g., 102 of FIG. 1) and providing the command to a command decoder (e.g., 106 of FIG. 1) and the address to an address decoder (e.g., 104 of FIG. 1). The method 800 may include receiving a row address along with the linked activation command and bank address. In some embodiments, the method may include receiving a linked bank address along with the linked activation command and bank address.

In some embodiments, the method may include determining if the activation command is a linked activation command or a normal activation command. For example, the method 800 may include determining if the activation command is a linked activation command or a normal activation command based on a state of a bit of a command address packet. If the command is a linked activation command, then box 810 may be followed by both boxes 820 and 830. If the command is a normal activation command, then box 810 may be followed by box 820 but box 830 may be skipped.

Box 820 describes activating a word line in a first bank associated with the bank address responsive to the linked activation command. Box 830 describes performing a refresh operation in a second bank which is in a bank link group with the first bank responsive to the linked activation command. In some embodiments, box 810 may include receiving a linked bank address which specifies the second bank. For example, if there are a plurality of banks in the bank link group which includes the first bank, the linked bank address may specify which of the plurality of banks in the bank link group is the second bank.

Activating the word line may include selecting a row decoder (e.g., 108 of FIGS. 1 and/or 220 of FIG. 2) associated with the first bank and activating a word line associated with a row address. Performing the refresh operation may include selecting a refresh control circuit (e.g., 116 of FIGS. 1 and/or 202 of FIG. 2) associated with the second bank. In some embodiments, the method may include determining whether or not to perform the refresh operation. For example, the method may include comparing a value of a refresh address counter (e.g., 206 of FIG. 2) to an expected number of refresh operations, and skipping the refresh operation if the value is at or ahead of the expected number of refresh operations. In some embodiments, the method may include performing a normal refresh operation (e.g., 522 of FIG. 5), performing one or more targeted refresh operations (e.g., 524 of FIG. 5) or skipping performing a refresh operation (e.g., 526 of FIG. 5).

The method 800 may include receiving a second activation command and a second bank address a first time after receiving the linked activation command if the second bank address is associated with a different bank link group than the first bank or a second time after receiving the linked activation command if the bank address is associated with a same bank link group as the first bank. The first time may be shorter than the second time. For example, the first time may be a normal bank to bank delay time, such as tRRD, while the second time may be a linked refresh delay tRFCL, such as shown in FIG. 6.

The method 800 may include receiving a second linked activation command and a second bank address. The second bank address is associated with a third bank which is not in the same bank link group as the first bank or the second bank. The method 800 may include activating a word line in the third bank responsive to the second linked activation command and performing a refresh operation in a fourth bank which is in a second bank link group with the third bank responsive to the linked activation command.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of memory banks including a first bank and a second bank;
a command decoder configured to receive an activation command a bank address associated with the first bank;
a refresh control circuit configured to perform a refresh operation on the second bank responsive to the activation command.

2. The apparatus of claim 1, wherein the activation command is a linked activation command.

3. The apparatus of claim 2, wherein a bit of the activation command indicates if the activation command is a linked activation command or a normal activation command, and wherein when the activation command is a normal activation command, the refresh control circuit does not perform the refresh operation on the second bank.

4. The apparatus of claim 1, wherein the bank address includes a linked bank address which specifies the second bank.

5. The apparatus of claim 1, wherein the refresh control circuit is configured to perform a normal refresh operation, a targeted refresh operation, or skip performing the refresh operation as the refresh operation on the second bank.

6. The apparatus of claim 1, wherein the command decoder is configured to receive a second activation command and a second bank address associated with the second bank,
the apparatus comprising a second refresh control circuit configured to perform a refresh operation on the first bank.

7. The apparatus of claim 1, further comprising a row decoder configured to activate a word line in the first bank.

8. A method comprising:
receiving a linked activation command and a bank address;
activating a word line in a first bank associated with the bank address responsive to the linked activation command; and
performing a refresh operation in a second bank which is in a bank link group with the first bank responsive to the linked activation command.

9. The method of claim 8, further comprising:
receiving a second activation command and a second bank address a first time after receiving the linked activation command if the second bank address is associated with a different bank link group than the first bank or a second time after receiving the linked activation command if the second bank address is associated with a same bank link group as the first bank.

10. The method of claim 9, wherein the first time is shorter than the second time.

11. The method of claim 8, further comprising:
receiving a second linked activation command and a second bank address, wherein the second bank address is associated with a third bank which is not in the same bank link group as the first bank or the second bank;
activating a word line in the third bank responsive to the second linked activation command; and
performing a refresh operation in a fourth bank which is in a second bank link group with the third bank responsive to the linked activation command.

12. The method of claim 8, further comprising determining whether or not to perform the refresh operation.

13. The method of claim 12, further comprising performing a normal refresh operation, at least one targeted refresh operation, or combinations thereof as the refresh operation.

14. The method of claim 8, receiving an activation command and determining if the activation command is a normal activation command or a linked activation command based on at least one bit of the activation command.

15. An apparatus comprising:
a plurality of memory banks;
a command address input circuit configured to receive a linked activation command, a bank address, and a linked bank address;
a row decoder configured to activate word line in a first memory bank of the plurality of memory banks, wherein the first memory bank is associated with the bank address; and
a refresh control circuit configured to perform a refresh operation on a second memory bank of the plurality of memory banks, wherein the second memory bank is associated with the linked bank address.

16. The apparatus of claim 15, wherein the command address input circuit is configured to receive a command address packet which includes the linked activation command, the bank address, the linked bank address, and a row address.

17. The apparatus of claim 16, wherein one or more bits of the command address packet is shared between the bank address and the linked bank address.

18. The apparatus of claim 15, wherein the first memory bank and the second memory bank are part of different bank groups.

19. The apparatus of claim 15, wherein the refresh control circuit is configured to perform a normal refresh operation, one or more targeted refresh operations, or skip performing a refresh operation as the refresh operation on the second memory bank.

20. The apparatus of claim 15, wherein the command address input circuit is further configured to receive a normal activation command and the bank address, and wherein the row decoder is configured to activate the word line in the first memory bank responsive to the normal activation command and the refresh control circuit is configured to not perform the refresh operation responsive to the normal activation command.
